(19) United States
(12) Patent Application Publication
(10) Pub. No.: US 2023/0216276 A1
(43) Pub. Date: Jul. 6, 2023

(54) SEMICONDUCTOR LIGHT-EMITTING ELEMENT, LIGHT-EMITTING DEVICE, AND RANGING DEVICE

(71) Applicant: CANON KABUSHIKI KAISHA, Tokyo (JP)

(72) Inventors: Takako Suga, Kanagawa (JP); Takeshi Uchida, Kanagawa (JP); Tatsuro Uchida, Tokyo (JP)

(21) Appl. No.: 18/090,617

(22) Filed: Dec. 29, 2022

(30) Foreign Application Priority Data
Jan. 1, 2022 (JP) 2022-000025
Oct. 4, 2022 (JP) 2022-160460

(51) Int. Cl. H01S 5/183; H01S 5/34; H01S 5/343; G01S 7/481; G01S 17/08

(52) U.S. Cl. CPC H01S 5/18313; H01S 5/3416; H01S 5/3432; G01S 7/4814; G01S 17/08; H01S 5/18347; H01S 5/426

(57) ABSTRACT

A semiconductor light-emitting element having a structure in which a substrate, a first reflector, a resonator cavity including an active layer, a second reflector and a transparent conductive film are stacked in this sequence, the semiconductor light-emitting element comprising: a first current constriction portion configured with an oxidation constriction layer; and a second current constriction portion configured with an insulation film, which is formed on an upper face of the second reflector and has an opening, and a contact portion between the transparent conductive film and a semiconductor layer with which the transparent conductive film is in contact, wherein a width d2 of the second current constriction portion is smaller than a width d1 of the first current constriction portion.

### BACKGROUND OF THE INVENTION

### Field of the Invention

The present invention relates to a semiconductor light-emitting element, a light-emitting device, and a ranging device.

### Description of the Related Art

A vertical cavity surface-emitting laser (VCSEL) is receiving attention as a light source for a time-of-flight (ToF) type light detection and ranging (LiDAR).

Higher power is demanded for light sources in order to improve ranging accuracy and to increase a measurable distance.

A possible method for implementing high power in VCSEL is to increase a light-emitting diameter. However, simply increasing a light-emitting diameter decreases the current density in a portion around the center of a light-emitting diameter, and increases the current density in a peripheral portion thereof. In other words, merely increasing the light-emitting diameter causes problems in beam control of a far field and in durability.

WO 2019/107273 discloses a substrate rear face-emitting type VCSEL, where a current constriction structure, which is different from the oxidation constriction, is disposed on the front face side of a substrate. By this configuration, current density not only in a peripheral portion but also in the portion around the center of the light-emitting diameter can be increased, while increasing the light-emitting diameter. However, in a case of the substrate rear face-emitting type VCSEL, light is absorbed by the substrate, hence such implementation may not be possible depending on the wavelength or high power may not be achieved.

Japanese Patent Application Publication No. 2006-114915 discloses a substrate front face-emitting type VCSEL where the current constriction structure, which is different from the oxidation constriction, is disposed on the front face of the device, which is the light-emitting side, by diffusion or ion implantation. By increasing the light-emitting diameter with use of this configuration as well, the current density can be increased not only in the peripheral portion but also in the portion around the center of the light-emitting diameter.

Japanese Patent Application Publication No. 2006-114915 discloses a method for forming a current constriction structure in which current flows only through the center portion, by implanting ions into the peripheral portion on the substrate front face, so as to increase the resistance of the peripheral portion. A problem that is generated in the case of forming the current constriction structure in this way will be described with reference to FIG. 13.

A VCSEL illustrated in FIG. 13 includes an electrode layer 701, an n-GaAs substrate 702, an n-DBR layer 704, an active region 706, an insulation layer (e.g. oxide) 707, a p-DBR layer 708, a p-GaAs layer 710 and an upper electrode 714. In such a VCSEL, a high resistance region 712 is formed by implanting ions into a peripheral portion of the p-GaAs layer 710, and a current path from the second electrode 714 to a current injecting region 720 is left in the upper portion of the p-GaAs layer 710. Further, a current path from the current injecting region 720 to an opening 716 is formed in the p-DBR 708. As a consequence, the thickness of the p-GaAs layer 710 must be formed in the μm order. With the distance of the current injecting region 720 in the vertical direction of the substrate becoming thick (μm order), the resistance increases, and as a result, the voltage of the entire semiconductor light-emitting element increases.

### SUMMARY OF THE INVENTION

With the foregoing in view, it is an object of the present invention to provide a semiconductor light-emitting element that easily controls beams in a far field at high power, while restraining an increase of voltage in the entire element.

One aspect of the present invention is a semiconductor light-emitting element having a structure in which a substrate, a first reflector, a resonator cavity including an active layer, a second reflector and a transparent conductive film are stacked in this sequence, the semiconductor light-emitting element comprising: a first current constriction portion configured with an oxidation constriction layer; and a second current constriction portion configured with an insulation film, which is formed on an upper face of the second reflector and has an opening, and a contact portion between the transparent conductive film and a semiconductor layer with which the transparent conductive film is in contact, wherein a width d2 of the second current constriction portion is smaller than a width d1 of the first current constriction portion.

According to the present invention, a semiconductor light-emitting element that easily controls beams in a far field at high power can be provide, while restraining an increase of voltage in the entire element. By using this semiconductor light-emitting element, a ranging device, which improves ranging accuracy and measurable distance, can be provided.

Further features of the present invention will become apparent from the following description of exemplary embodiments with reference to the attached drawings.

### BRIEF DESCRIPTION OF THE DRAWINGS

FIG. 1 is a diagram depicting an embodiment of the present invention;

FIGS. 2A and 2B are graphs indicating distribution and change of current density according to an embodiment of the present invention;

FIG. 3 is a diagram depicting Example 1;

FIG. 4 is a diagram depicting Example 2;

FIG. 5 is a diagram depicting Example 3;

FIGS. 6A and 6B are graphs indicating distribution and change of current density according to Example 3;

FIG. 7 is a diagram depicting Example 4;

FIG. 8 is a diagram depicting Example 5;

FIG. 9 is a diagram depicting Example 6;

FIG. 10 is a diagram depicting Example 7;

FIG. 11 is a diagram depicting Example 8;

FIG. 12 is a diagram depicting Example 9; and

FIG. 13 is a diagram depicting a comparative example.

### DESCRIPTION OF THE EMBODIMENTS

Embodiments of the present invention will be described. The present invention is not limited to the following embodiments, and includes changes and modifications performed on the following embodiments based on common knowledge of an expert skilled in the art, without departing from the spirit and scope of the present invention.

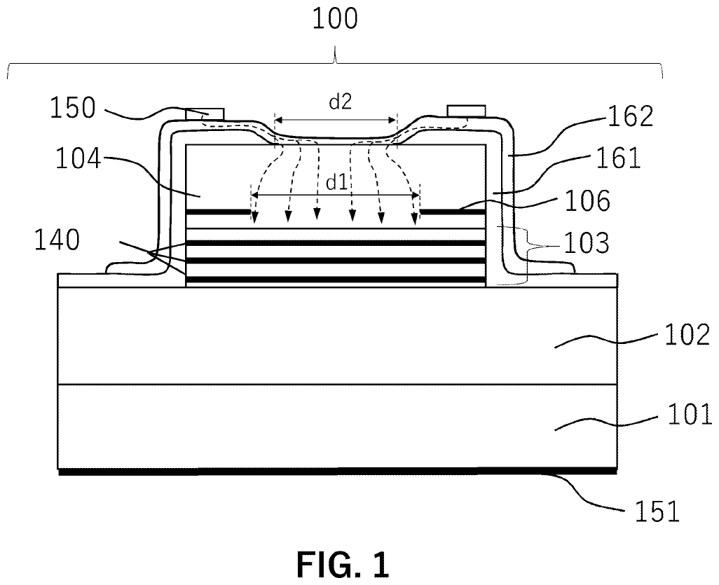

A semiconductor light-emitting element 100 according to an embodiment of the present invention will be described with reference to FIG. 1. The semiconductor light-emitting element 100 includes a substrate 101, a first distributed Bragg reflector (DBR) 102, a semiconductor resonator cavity 103 and a second DBR 104. The first DBR 102 and the second DBR 104 correspond to the first reflector and the second reflector of the present invention respectively.

A plurality of quantum well layers 140 are disposed in the resonator cavity 103. An AlGaAs layer, of which Al composition is higher than the other layers, is included in a part of the second DBR 104. An oxidation constriction layer 106, of which periphery is insulated, is formed by performing steam oxidation on the AlGaAs layer. The oxidation constriction layer 106 corresponds to the first current constriction portion. In FIG. 1, only the insulated portion is indicated by the reference number 106, but the non-oxidized center portion of the semiconductor layer also corresponds to the oxidation constriction layer 106.

Here the second DBR 104 is formed by a semiconductor. As another mode of the present invention, a third DBR, which is different from the second DBR, may further be disposed on the second DBR, and details thereof will be described later in Example 5.

The resonator cavity 103 and the second DBR 104 are processed to be tubular mesa-shaped, and are covered with an insulation film 161. A transparent conductive layer 162 is formed on the insulation film 161.

An upper electrode 150 electrically contacts with a part of the transparent conductive layer 162. A lower electrode 151 is in ohmic contact with the rear face of the substrate 101.

As illustrated in FIG. 1, the insulation film 161, of which center portion is partially removed, is formed on the upper face of the second DBR 104 which has been processed to be tubular mesa-shaped. The portion where the insulation film 161 has been removed is hereafter called the “insulation opening”. In the insulation opening, the transparent conductive layer 162 is in contact with the upper face of the second DBR 104. By this insulation opening, a contact portion, which is configured with the transparent conductive layer 162 and the upper face of the second DBR 104, is provided. The shape of the insulation opening may be a circle, ellipse, polygon or a shape similar thereto. If the shape of the insulation opening includes an acute angle portion, current tends to concentrate at this portion, which is not desirable in terms of the current profile and durability, that is, the shape of the insulation opening is preferably a shape close to a circle. Carriers supplied from the upper electrode 150 flow into the second DBR 104 only through the contact portion of the insulation opening. In other words, the second current constriction portion is formed by: the insulation film 161 having the insulation opening; and the contact portion between the second DBR 104 and the transparent conductive layer 162. In the case where the shape of the second current constriction portion is a circle, for example, the diameter thereof is d2.

As illustrated in FIG. 1, in a case where the cross-sectional shape of the insulation film 161 is tapered to be thinner closer to the center portion, the size of the second constriction structure is defined by the distance d2 at the tip portion. In other words, d2 is the substantial size in which the current is constricted by the second constriction structure.

In FIG. 1, the mesa shape is formed from the second DBR 104 to the resonator cavity 103, but required here is that the tubular mesa shape is formed at a depth that is lower than the oxidation constriction layer 106. This means that the mesa shape may be formed at a depth in the middle of the resonator cavity 103, or may be formed at the depth in the middle of the first DBR 102.

The present embodiment describes a structure where the light-emitting element is processed in the tubular mesa shape, but the present invention is not limited thereto. For example, instead of uniformly processing the periphery to be a tubular shape, the oxidation constriction layer 106 may be formed by removing a part of the portion down to a target depth by etching, then insulating the periphery by steam oxidation.

Further, in FIG. 1, there is one layer of the transparent conductive layer 162, but one or more transparent insulation films (e.g. SiOx, SiNx, TiOx) may be stacked thereon when necessary. In this case, a part of the insulation film below the upper electrode 150 is removed so that the upper electrode 150 and the transparent conductive layer 162 are electrically connected.

When a high refractive index layer and a low refractive index layer, both of which optical film thickness is λc/4, form a pair, the first DBR 102 is configured with a plurality of the pairs that are stacked. λc is a central wavelength of the high reflection band of the first DBR 102.

The quantum well layer 140 has a configuration where a well layer is sandwiched by barrier layers, and is an active layer of the resonator cavity 103.

When a high refractive index layer and a low refractive index layer, both of which optical film thickness is λc/4, form a pair, the second DBR 104 is configured with a plurality of the pairs that are stacked. A part of the high refractive index layer on the top layer, however, is replaced with a contact layer of which carrier density is higher than the other layers, so as to improve the electric contact properties with the transparent conductive layer 162. Furthermore, in the second DBR 104, a part of the high refractive index layer closest to the quantum well layer (active layer 140) is replaced with an AlGaAs layer of which Al composition is higher than the other layers. After the mesa of the VCSEL 100 is formed, this AlGaAs layer is oxidized from the size well of the mesa for a predetermined length from the side wall of the mesa by steam oxidation, whereby the oxidation constriction layer 106 having insulation properties is formed on the periphery thereof.

The width d2 of the second current constriction, that is, the insulation opening portion where the insulation film 161 is removed, is shorter than the width d1 of the semiconductor portion on the inner side of the oxidation constriction layer 106, which is the first current constriction (this semiconductor portion is a portion where the current can flow, and is hereafter called the “non-oxidized portion”). That is, d1 and d2 satisfy the following formula (1).

d2<d1 (1)

Here, the case where the shapes of the non-oxidized portion (semiconductor portion on the inner side of the oxidation constriction layer 106) and the second current constriction are circles will be described below, however the shape is not limited to a circle, but may be an ellipse, polygon or a shape similar thereto. In this case, each width d1 and d2 when sectioned at a certain cross-section satisfies formula (1).

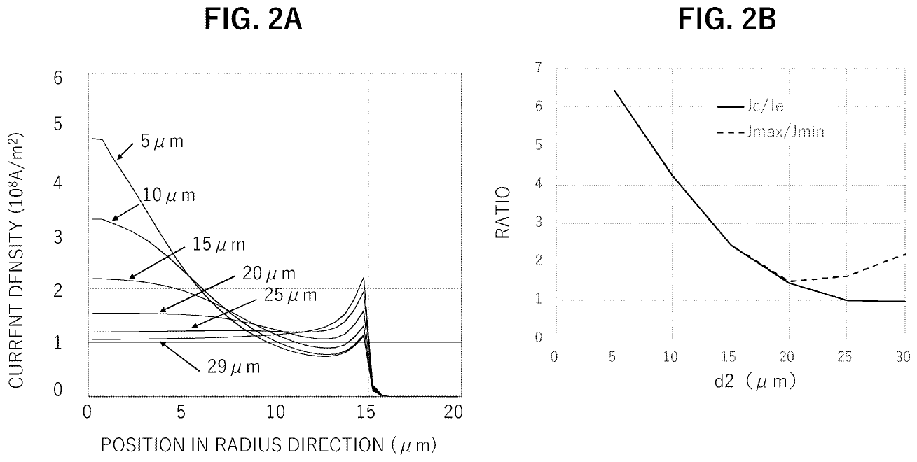

The effect of the above configuration will be described based on the calculation result indicated in FIG. 2A. The element configuration used for this calculation model is based on the configuration of Example 1 which will be described later.

FIG. 2A indicates a distribution of a current density that flows into the quantum well layer 140 in the case where the diameter d2 of the insulation opening changes from 5 μm to 29 μm when the oxidation constriction diameter d1 is 30 The abscissa in FIG. 2A indicates a position in the radius direction where the center of the mesa (that is, the center of the non-oxidized portion) is position 0.

The solid line in FIG. 2B indicates the state of change when the current density in the center portion is Jc, and the minimum value of the current density in the peripheral portion (10 μm portion from the peripheral edge of d1 toward the center portion) is Je.

A far field image can be controlled by controlling the current density distribution of current flowing into the quantum well layer to be higher in the center portion compared with the peripheral portion. In other words,

Jc>Je (2)

is preferable.

Furthermore,

Jc>2×Je (3)

is even more preferable.

According to FIGS. 2A and 2B, the current density distribution, of which center portion protrudes, can be formed in a range where the diameter d2 of the insulation opening portion is smaller than 25 that is, in a range where formula 2 is satisfied. Further, the current density profile protrudes even more in the center portion in a range where d2 is smaller than 15 that is, in a range where formula 3 is satisfied.

Here, if the current density that concentrates in the peripheral portion of the oxidation constriction diameter is expanded toward the center portion, the generation of non-light emission recoupling and the like that spreads from the peripheral portion is restrained, hence durability of the element improves. The dotted line in FIG. 2B indicates the state of the change of Jmax/Jmin in the current density in the non-oxidized portion, where Jmax is the maximum value and Jmin is the minimum value. In the range where d2 is smaller than 20 μm, Jmax/Jmin (dotted line) is approximately the same as Jc/Je (solid line).

In terms of durability, it is preferable to satisfy

Jmax<3.3×Jmin (4)

Durability in general is inversely proportional to the square of the current density, hence by satisfying the condition of formula 4, the in-plane dispersion of the local durability in the non-oxidized portion can be confined to within one digit.

If focus is placed on the far field profile rather than durability, then

Jmax<10×Jmin (5)

may be used. By satisfying the conditions of formula (5), the dispersion of the local durability in the non-oxidized portion can be confined to within two digits.

The three elements of the preferable device configuration, the non-oxidation constriction diameter d1 and the diameter d2 of the insulation opening mutually influence each other, and are determined in accordance with the applications or the requirements. For example, in a case where the device configuration illustrated in FIG. 1 has a 30 μm non-oxidation constriction diameter d1 as indicated in the later mentioned Example 1, a preferable value of the diameter d2 of the insulation opening is 12 to 18 μm if focus is placed on durability. The value of the diameter d2 may be 12 μm or less for the applications where focus is placed on the far field profile rather than on durability.

If the device configuration changes, the appropriate ranges of d1 and d2 also change accordingly, so preferable ranges thereof are selected in accordance with the application.

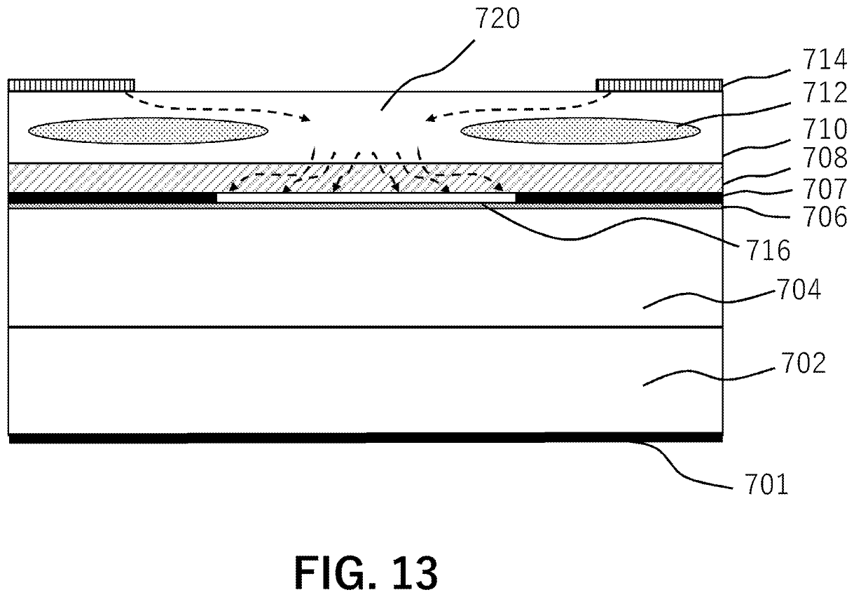

In the present invention, the transparent conductive layer 162 is disposed on the second DBR 104 in order to form the second current constriction structure. The transparent conductive layer 162, which can be thinner than the p-GaAs layer used for the prior art (FIG. 13), can decrease the resistance of the second constriction structure. As a result, compared with the case of using the ion implantation method, the voltage increase in the second current constriction structure portion, with respect to the entire VCSEL 100, can be reduced by about one digit. Therefore by using this element as a light source, a ranging device which not only improves ranging accuracy and measurable distance but also implements a smaller size and a lighter weight can be provided.

Now examples of the present invention will be described in more detail with reference to a concrete layer configuration and the like of the light-emitting element.

### Example 1

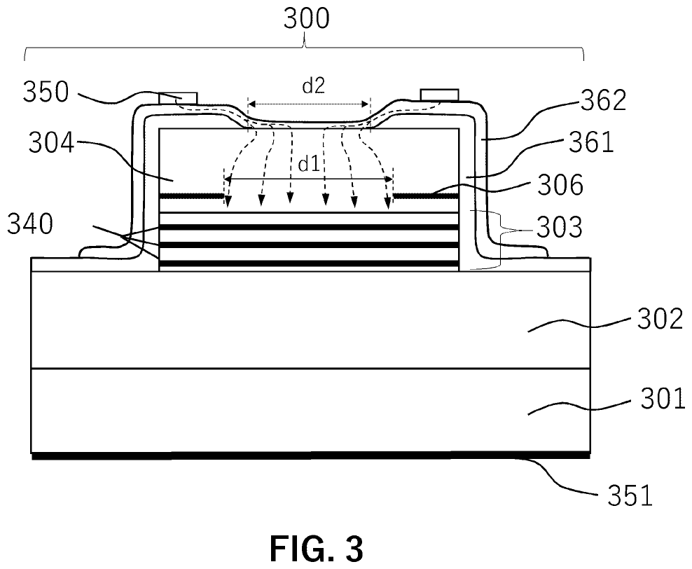

A VCSEL 300 according to Example 1 will be described with reference to FIG. 3. FIG. 3 is a cross-sectional view of the VCSEL 300 of Example 1. The VCSEL 300 is configured by a GaAs substrate 301, a first DBR 302, a semiconductor resonator cavity 303, and a second DBR 304, which are stacked in this sequence. In FIG. 3, these members are directly in contact with each other, but another member may be disposed there between. The above description is for describing the structure and is not intended to limit the sequence of manufacturing each member.

Three quantum well layers 340 are disposed in the resonator cavity 303. An Al_{0.98}GaAs is oxidized in a part of the second DBR 304 by steam oxidation, whereby an oxidation constriction layer 306, which has insulation properties, is formed.

The resonator cavity 303 and the second DBR 304 are processed to be tubular mesa-shaped, and are covered with an insulation film 361. Furthermore, an indium tin oxide (ITO) layer 362 is formed on the insulation film 361.

As illustrated in FIG. 3, the insulation film 361, of which center portion is partially removed, is formed on the upper face of the second DBR 304 which has been processed to be mesa-shaped, and in this removed portion, the ITO layer 362 is in contact with the upper face of the second DBR 304. The portion where the insulation film 361 has been removed is hereafter called the “insulation opening”. This means that the ITO layer 362 is in contact with the upper face of the second DBR 304 in the insulation opening portion. The shape of the insulation opening is a circle in Example 1. An upper ring electrode 350 is electrically in contact with a part of the ITO layer 362. A lower common electrode 351 is in ohmic contact with the rear face of the GaAs substrate 301.

When an Al_{0.1}GaAs layer and an Al_{0.9}GaAs layer, both of which optical film thickness is λc/4, form a pair, the first DBR 302 is configured with 35 pairs that are stacked. λc is a central wavelength of the high reflection band of the first DBR 302, and is 940 nm in Example 1.

The quantum well layer 340 has a configuration where an 8 nm thick In_{0.1}GaAs layer is sandwiched by 10 nm thick Al_{0.1}GaAs barrier layers. In Example 1, three quantum well layers are disposed in the resonator cavity 303.

When an Al_{0.1}GaAs layer and an Al_{0.9}GaAs layer, both of which optical film thickness is λc/4, form a pair, the second DBR 304 is configured with 20 pairs that are stacked. A part of the Al_{0.1}GaAs layer on the top layer, however, is replaced with a GaAs contact layer of which thickness is 50 nm and carrier density is 1×10¹⁹ cm⁻³, so as to improve the electric contact properties with the transparent conductive layer (ITO layer) 362. Furthermore, a part of the Al_{0.1}GaAs layer closest to the quantum well layer 340 of the second DBR 304 is replaced with an Al_{0.98}GaAs layer of which thickness is 30 nm. After the mesa of the VCSEL 300 is formed, the Al_{0.98}GaAs layer is oxidized from the side wall of the mesa for a predetermined length from the edge of the mesa by steam oxidation, whereby the oxidation constriction layer 306 having insulation properties is formed on the periphery thereof.

The optical film thickness of the ITO layer 362 is assumed to be λc/2.

The diameter d2 of the insulation opening portion where the insulation film 361 is removed is 10 μm, and the diameter d1 of the semiconductor portion (that is, a portion through which current can flow, that is, the non-oxidized portion) on the inner side of the oxidation constriction layer 306 is 30 μm. Since the non-oxidized portion is a portion of the resonator cavity 103 through which current can flow, the diameter of the non-oxidized portion is the light-emitting diameter of the VCSEL. This aspect of Example 1 is the same in Example 2 and in later examples.

In Example 1, as indicated in FIGS. 2A and 2B, the profile of the current density distribution of the current that flows into the quantum well layer 340 can be formed to protrude in the center portion, whereby the far field image can be controlled. In the configuration of Example 1, the values of Jc/Je and Jmax/Jmin are 4.2. In Example 1, a value greater than 3.3 is selected for the value of Jmax/Jmin since short time use is assumed. In the case of placing focus on the life factor, on the other hand, d2 may be set to 15 μm, for example. In this case, the values of Jc/Je and Jmax/Jmin become 2.4.

Further, the second constriction structure is formed by forming the thin transparent conductive layer 362 (about 300 nm thick) on the second DBR 304. Therefore the voltage increase in the second constriction structure with respect to the entire VCSEL 300 can be reduced by about one digit compared with the ion implantation method. By using the light-emitting element of Example 1 as a light source, a ranging device which not only improves the ranging accuracy and the measurable distance but also implements a smaller size and lighter weight can be provided.

### Example 2

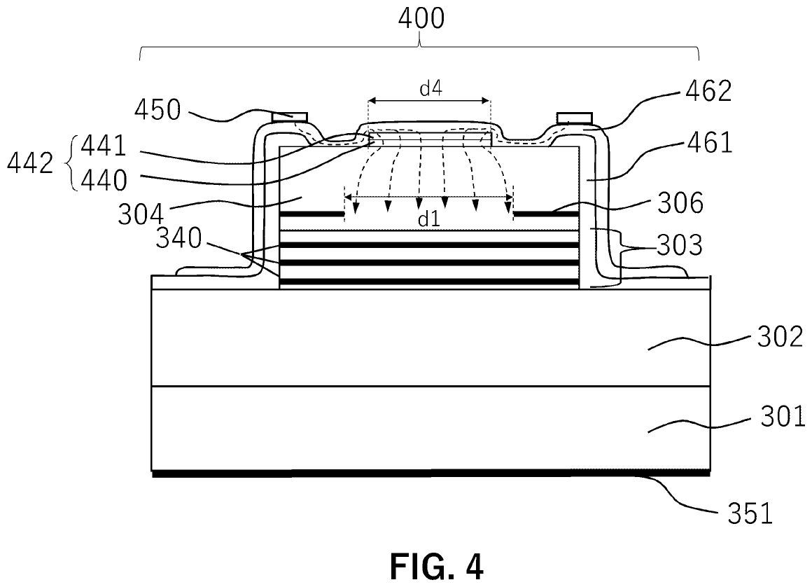

A VCSEL 400 according to Example 2 will be described with reference to FIG. 4. In Example 2, the current constriction function on the upper face of the second DBR by restricting the contact region, similar to Example 1, is implemented without forming the insulation opening.

FIG. 4 is a cross-sectional view of the VCSEL 400 of Example 2. The configuration of the portion from the lower common electrode 351 to the second DBR 304 in FIG. 4 is the same as Example 1, hence these composing elements are denoted with the same reference numbers as Example 1 respectively, and description thereof is omitted.

On the second DBR 304, a tunnel junction layer 442 is disposed. As illustrated in FIG. 4, the tunnel junction layer 442 is disposed on the outermost surface of the second DBR 304 only in the diameter d4 portion from the mesa center. The diameter d4 is smaller than the diameter d1 of the non-oxidized portion of the oxidation constriction layer 106. Out of the upper face of the tunnel junction layer 442 and the upper face of the second DBR 304, an ITO layer 462 is formed on the portion where the tunnel junction layer 442 is not disposed. The optical thickness of the ITO layer 462 can be an integral multiple of λc/2, but λc/2 is preferable if conductivity in the horizontal direction of the substrate has no problem, since even the ITO layer to a degree absorbs light. An upper ring electrode 450 is disposed on the ITO layer 462.

The tunnel junction layer 442 is configured with at least two layers, that is, a p-type GaAs layer 440 which has been doped to a carrier density of 5×10¹⁹ cm⁻³, and an n-type GaAs layer 441 which has been doped to a carrier density of 1×10¹⁹ cm⁻³ sequentially from the substrate side. The total optical film thickness of these two layers is set to an integral multiple of λc/2. For example, the actual thickness of the n-type GaAs layer 441 is set to 190 nm.

In the case where absorption in a high doped p-type GaAs layer is a problem, the p-type GaAs layer 440 may be configured with a plurality of layers. For example, a two-layer configuration configured with: a layer on the substrate side which is doped to a carrier density of 1×10¹⁸ cm⁻³; and a layer thereon (layer in contact with the n-type GaAs layer 441) which is a thin layer (e.g. 20 nm thickness) doped to a carrier density of 1×10¹⁹ cm⁻³, may be used.

In a case where an etching stop layer is needed in the patterning of the tunnel junction layer 442, the etching stop layer may be formed between the second DBR 304 and the tunnel junction layer 442. The optical film thickness of the etching stop layer is set to be an integral multiple of λc/2.

The tunnel junction layer, where the p-type layer and the n-type layer, both of which carrier density exceeds 1×10¹⁸ cm⁻³, are joined like this, is a tunnel diode, hence by the tunnel effect, current also flows in the opposite direction via a thin depletion layer which is generated on the p-n junction interface. Therefore if voltage is applied between the upper ring electrode 450 and the lower electrode 151 so that the upper ring electrode 450 becomes positive, current flows from the upper ring electrode 450 to the second DBR 304 via the ITO layer 462 and the tunnel junction layer 442. The current that flows into the second DBR 304 diffuses inside the second DBR 304, just like the configuration in FIG. 3 in Example 1, and the current density distribution of the current injected into the active layer becomes the current density distribution of which center is high and protruded.

As described above, the far field image can also be controlled using the configuration of Example 2, just like Example 1. Further, by spreading the current density, which concentrates to the peripheral portion of the oxidation constriction diameter, to the center portion, the generation of non-light emission recoupling or the like, that spreads from the peripheral portion, is restrained, hence durability of the element improves.

Further, the second constriction structure is formed by disposing the thin transparent conductive film 462 and the tunnel junction layer 442 on the second DBR 304. The tunnel junction layer has low resistance, since both the p-type layer and the n-type layer are high doped layers of which carrier density is in the 10¹⁹ order. Therefore the voltage increase in the second constriction structure, with respect to the entire VCSEL 400, can be reduced by about one digit compared with the ion implantation method. By using the light-emitting element of Example 2 as a light source, a ranging device, which not only improves ranging accuracy and the measurable distance but also implements a smaller size and a lighter weight, can be provided.

### Example 3

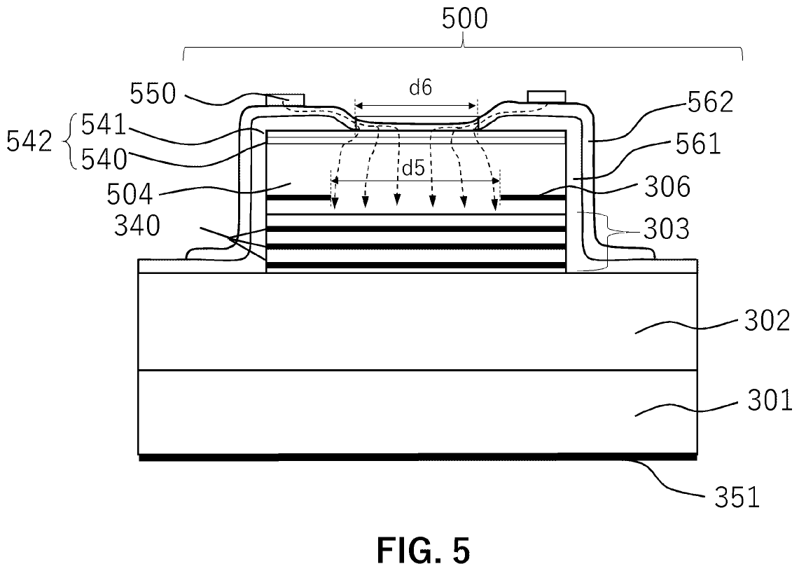

A VCSEL 500 according to Example 3 will be described with reference to FIG. 5. A common aspect with Example 1 is disposing the insulation opening and a common aspect with Example 2 is disposing the tunnel junction layer. Differences from Examples 1 and 2 will be mainly described below.

FIG. 5 is a cross-sectional view of the VCSEL 500 in Example 3. The VCSEL 500 is configured by the GaAs substrate 301, the first DBR 302, the semiconductor resonator cavity 303, a second DBR 504 and a tunnel junction layer 542, which are stacked in this sequence.

The resonator cavity 303, the second DBR 504 and the tunnel junction layer 542 are processed to be tubular mesa-shaped, and are covered with an insulation layer 561. An ITO layer 562 is formed on the insulation layer 561.

As illustrated in FIG. 5, the insulation layer 561, of which center portion is partially removed, is formed on the upper face of the second DBR 504 which has been processed to be mesa-shaped, and in this insulation opening, the ITO layer 562 is in contact with the upper face of the tunnel junction layer 542. The shape of the insulation opening is a circle in Example 3. An upper ring electrode 550 is electrically in contact with a part of the ITO layer 562. A lower common electrode 351 is in ohmic contact with the rear face of the GaAs substrate 301.

The tunnel junction layer 542 is configured with a p-type GaAs layer 540 which has been doped to a carrier density of 5×10¹⁹ cm⁻³, and a n-type GaAs layer 541 which has been doped to a carrier density of 1×10¹⁹ cm⁻³. The tunnel junction layer, where the p-type layer and the n-type layer both of which carrier density exceeds 1×10¹⁸ cm⁻³ are joined like this, is a tunnel diode. Hence by the tunnel effect, current also flows in the opposite direction via a thin depletion layer which is generated on the p-n junction interface by the tunnel effect, just like the case of the tunnel junction layer 442 of Example 2.

In Example 3, the configuration where an opening exists in a part of the insulation film in the upper portion of the mesa is the same as Example 1, but a diameter d6 of the insulation opening and a diameter d5 of the non-oxidation portion that are preferable are different from Example 1, because the tunnel junction layer 542 exists in Example 3. The effect of this configuration will be described below.

In Example 3, a diameter d6 of the insulation opening portion where the insulation layer 561 is removed is 20 μm, and a diameter d5 of the non-oxidized portion on the inner side of the oxidation constriction layer 306 is 70 μm.

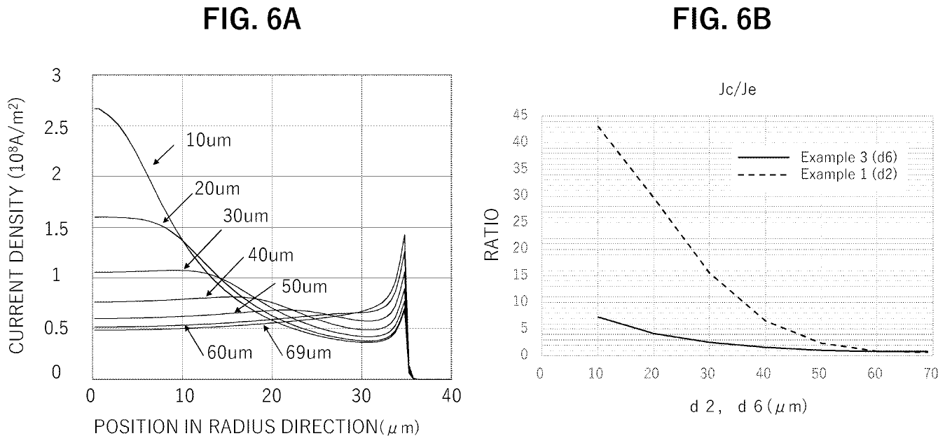

The effect of this configuration will be described based on the calculation result indicated in FIG. 6A. In FIG. 6A, the abscissa indicates a position in the non-oxidized portion in the radius direction, and the ordinate indicates a current density, and values in the graph indicate each value of the diameter d6 of the insulation opening portion. FIG. 6A indicates a distribution of the current density when d5 is fixed to 70 μm, and d6 is changed in the range of 10 μm to 69 μm. As indicated in FIG. 6A, the current density distribution maintains the profile of which center protrudes if d6 is up to 30 μm. In this case, current can be injected into the boundary of the oxidized portion and the non-oxidized portion, that is, the position of 35 μm in the abscissa in FIG. 6A.

The solid line in FIG. 6B indicates the ratio of Jc/Je in the case where d5 is fixed to 70 μm and d6 is changed. As indicated in FIG. 6B, formula 3 is satisfied when d6 is smaller than about 35 μm.

For comparison, the dotted line indicates the case of Example 1. The case of Example 1 is the case where d1 is 70 μm in the structure of Example 1. Jmax/Jmin is approximately the same as Jc/Je when d2 or d6 is 30 μm or more, hence it is not indicated here.

By the same calculation, a value of d2 or d6, that satisfies formula 3 and formula 5 simultaneously when d1 or d5 is an arbitrary value, can be determined. Table 1 indicates the value of d2 or d6 that satisfies formula 3 and formula 5 simultaneously when d1 to d5 is 30, 50, 70 and 100

TABLE 1

| | Example1 | Example3 |
|---|---|---|
| Diameter of the first | Diameter of the second | Diameter of the second |
| constriction portion | constriction portion | constriction portion |
| d1 or d5 (μm) | d2 (μm) | d6 (μm) |
| 30 | 13-17 | None |
| 50 | 30-36 | 10-19 |
| 70 | 40-52 | 25-35 |
| 100 | —(Uncalculated) | 50-59 |

As Table 1 indicates, in the case of Example 1, a minimum value of the preferable range of d2 is 4 μm when d1 is 30 to 70 and the allowable range of d2 becomes the maximum (6 μm) when d1 is 50 In Example 3, on the other hand, the preferable range of d6 is at least 9 μm when d5 is at least in the 50 to 100 μm range.

As described above, in Example 3, the tunnel junction layer 542 is disposed on the highest portion of the mesa, and the carriers spread in the direction parallel with the substrate, particularly by the n-type GaAs layer 541 in the tunnel junction layer 542. Therefore compared with Example 1, desirable current density distribution can be implemented even if the light-emitting area is increased.

According to Example 3, the diameter of the non-oxidized portion can be set to be larger compared with Example 1, hence a higher power light-emitting element can be implemented.

In the description of Example 3, the tunnel junction layer 542 is located on the upper side of the second DBR 504, but the tunnel junction layer may be disposed instead on the high refractive index layer which is the uppermost layer of the second DBR 504. In this case, the film thickness is set such that the optical film thickness of the tunnel junction layer becomes an odd multiple of λc/4. In the case of Example 3, carriers diffuse in the horizontal direction in the n-type GaAs layer 541, hence this film thickness need to be relatively thick. For example, this film thickness is set to 190 nm and the optical film thickness of the tunnel junction layer is set to 3λc/4.

Further, in Example 3, the tunnel junction layer 542 is formed on the entire upper surface of the second DBR 304, but the tunnel junction layer 542 need not be disposed at least in the peripheral portion of the mesa structure. For example, the tunnel junction layer 542 may be formed to have a diameter that includes the center of the mesa and is longer than d5, so as to include the entire non-oxidized portion of the oxidation constriction layer 306 in the planar view.

### Example 4

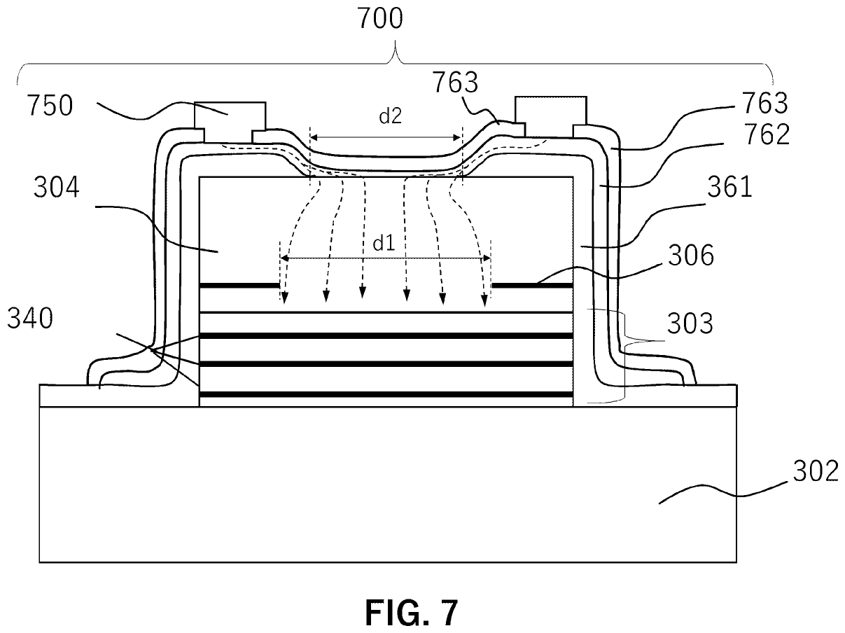

A VCSEL 700 according to Example 4 will be described with reference to FIG. 7. In Example 4, absorption of light by the ITO layer is reduced by decreasing the film thickness of the ITO layer.

Example 4 will be described based on the above mentioned Example 1. Composing elements the same as Example 1 are denoted with the same reference numbers as Example 1 respectively, and description thereof is omitted. In FIG. 7, only the configuration above the first DBR 302 is illustrated.

If absorption by the ITO layer is high and this influences the oscillation and output of the VCSEL in Example 1, the film thickness of the ITO layer may be decreased to be thinner than λc/2, and the transparent insulation layer or a plurality of layers may be disposed thereon, as Example 4.

In the VCSEL 700 described in Example 4, the insulation film 361, of which center portion is partially removed, is formed on the upper face of the second DBR 304 which has been processed to be mesa-shaped, and in this insulation opening, an ITO layer 762 is in contact with the upper face of the second DBR 304. Here the film thickness of the ITO layer 762 is assumed to be 100 nm. Then a transparent insulation film layer 763 (e.g. SiOx) is formed thereon so that the total optical film thickness of the ITO layer 762 and the transparent insulation film layer 763 becomes an integral multiple of λc/2. An upper ring electrode 750 is electrically connected with a part of the ITO layer 762 at the portion where the transparent insulation film layer 763 is partially removed.

In a case where deviation of the optical film thickness of the ITO layer 762 from λc/2 causes a drop in reflectance in the insulation opening and this drop becomes a problem, a plurality of transparent insulation film layers may be further formed on the transparent insulation film layer 763. The reflectance in the insulation opening can be improved by making the thickness of the transparent insulation film in contact with the ITO layer 762 to be λc/2 when added with the thickness of the ITO layer 762, then alternately stacking two types of layers having mutually different refractive indexes so that the optical film thickness becomes λc/4.

In the case of forming additional transparent insulation film on the transparent insulation film layer 763, an opening the same as that of the transparent insulation film layer 763 is formed on these transparent insulation film layers as well, so that the upper ring electrode 750 and the ITO layer 762 are electrically connected.

According to Example 4, in addition to the effect of Example 1, absorption by the ITO layer can be reduced, hence light-emitting efficiency can be further improved. Further, the risk of stopping oscillation due to a decrease in reflectance can be reduced.

Example 4 is based on Example 1, but the present invention is not limited thereto, and may be applicable to configurations of other examples and embodiments.

In Example 4, the thickness of the ITO layer 762 is 100 nm, but the thickness of the ITO layer can be thinner as long as the increase in the resistance value from the upper ring electrode to the tunnel junction portion, caused by electric conductivity, does not become a problem. Considering the probability of disconnection that may be caused by the step difference of the insulation opening, however, the thickness of the ITO layer is preferably 10 nm or more.

### Example 5

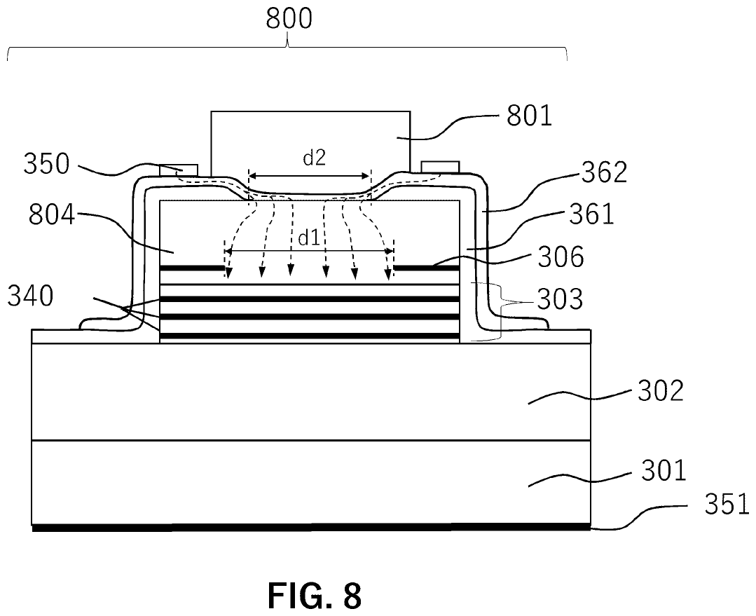

A VCSEL 800 according to Example 5 will be described with reference to FIG. 8. A difference from Example 1 is that the VCSEL 800 further includes a third DBR 801 on the ITO layer 362. The third DBR 801 is configured with multilayered dielectric film, such as SiOx, SiNx and TiOx.

In Example 1, the size of d2 is 10 μm or 15 μm. 15 μm is a design value when focus is placed on durability. In some cases, it may be difficult to set d2 to 15 μm or less due to process restrictions or the like. In Example 5, in order to increase the values of Jc/Je and Jmax/Jmin in such a case, the thickness of a second DBR 804 is set to be thinner than the thickness which was set in Example 1, and the reflectance that is reduced thereby is compensated for by disposing the third DBR 801.

Specifically, when the thickness of the second DBR 804 is ⅗ of Example 1, 4.4 can be acquired as the set value of both Jc/Je and Jmax/Jmin, even if d2 is 15 μm.

The size of the third DBR 801 in the horizontal direction on the paper surface of FIG. 8 must be sufficiently large optically as a resonator above the active layer. In FIG. 8, the size of the third DBR 801 is smaller than the inner diameter of the upper ring electrode 350 and is larger than d1, but the present invention is not limited thereto. The size of the third DBR 801 may be about the same or larger than the inner diameter of the upper ring electrode 350, as long as current can be supplied to the upper ring electrode 350 in this configuration.

In Example 5, the thickness of the second DBR 804 is set to be thinner than what was set in Example 1, but in order to acquire desirable current density distribution, the thickness of the second DBR 804 may be set to be thicker than that of Example 1. In this case, one layer or a plurality of layers of the second DBR may be set to ¾ λc, for example.

### Example 6

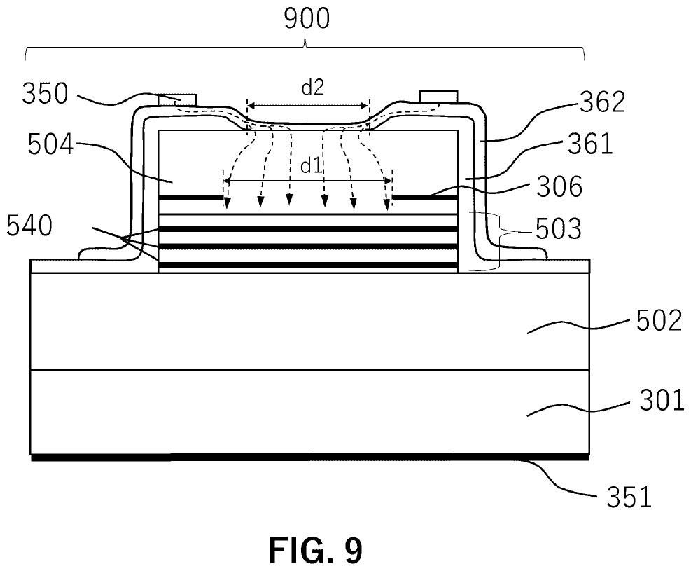

A VCSEL 900 according to Example 6 of the present invention will be described with reference to FIG. 9. A difference of VCSEL 900 from Example 1 is that kc is 850 nm. Therefore in the first DBR 502 and the second DBR 504, the optical film thickness of each layer is changed to be λc/4 (=212.5 nm). The composition and the optical film thickness of the quantum well layer 540 and the resonator cavity 503 are also appropriately adjusted.

Specifically, the quantum well layer 540 is configured such that an 8 nm thick GaAs layer is sandwiched by 8 nm thick Al_{0.3}GaAs barrier layers. In Example 6, three quantum well layers are disposed in the resonator portion 503.

Thereby even for an 850 nm band wavelength of which absorption rate in the substrate is high, and with which implementing high power is difficult in rear face emission, a high power semiconductor light-emitting element can be provided with restraining the influence of absorption by the substrate.

Example 6 has a configuration of Example 1 where the oscillation wavelength is changed, but can be applied to any of Examples 2 to 5 of the present invention.

### Example 7

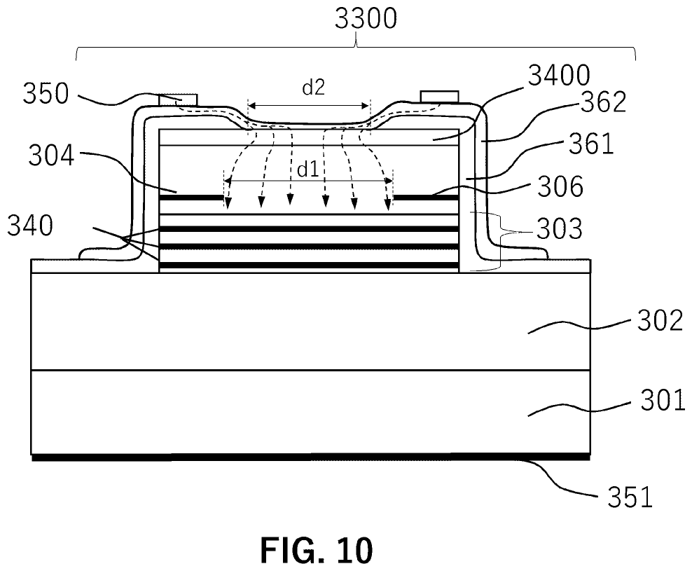

A VCSEL 3300 according to Example 7 will be described with reference to FIG. 10. FIG. 10 is a cross-sectional view of the VCSEL 3300 of Example 7. Unlike the VCSEL 300 of Example 1, a thick film contact layer 3400 is disposed between the second DBR 304 and the ITO layer 362 in Example 7. In Example 7, the thick film contact layer 3400 is a p-type GaAs layer of which optical film thickness is λc/2.

The VCSEL 3300 is configured by the GaAs substrate 301, the first DBR 302, the semiconductor resonator cavity 303, the second DBR 304 and the thick film contact layer 3400, which are stacked in sequence. In FIG. 10, these members are directly in contact with each other, but another member may be disposed there between. The above description is for describing the structure, and is not intended to limit the sequence of manufacturing each member.

Three quantum well layers 340 are disposed in the resonator cavity 303. An Al_{0.98}GaAs is oxidized in a part of the second DBR 304 by steam oxidation, whereby an oxidation constriction layer 306 having insulation properties is formed on the periphery thereof.

The resonator cavity 303, the second DBR 304 and the thick film contact layer 3400 are processed to be tubular mesa-shaped, and are covered with the insulation film 361. Furthermore, the indium tin oxide (ITO) layer 362 is formed on the insulation film 361.

As illustrated in FIG. 10, the insulation film 361, of which center portion is partially removed, is formed on the upper face of the thick film contact layer 3400 which has been processed to be mesa-shaped, and in this removed portion, the ITO layer 362 is in contact with the upper face of the thick film contact layer 3400. The portion where the insulation film 361 has been removed is called the “insulation opening” in the present description. The ITO layer 362 is in contact with the upper face of the thick film contact layer 3400 in the insulation opening portion. In other words, a contact portion is configured with the ITO layer 362 and the semiconductor layer which is in contact with the ITO layer 362. The shape of the insulation opening is a circle in Example 7. The upper ring electrode 350 is electrically in contact with a part of the ITO film 362. The lower common electrode 351 is in ohmic contact with the rear face of the GaAs substrate 301.

The layer constituting the DBR preferably has an optical film thickness that is an odd multiple of λc/4, and no longer functions as a reflection layer as the optical film thickness becomes close to λc/2. The thick film contact layer 3400 of Example 7 has an optical film thickness of λc/2, hence is not a layer of the DBR. As described above, in the VCSEL 3300 of Example 7, the portion that functions as the DBR constituting the VCSEL is not in direct contact with the ITO layer, unlike the VCSEL 300 of Example 1. Still, even in Example 7, just like Example 1, the current distribution flowing into the quantum well layer can be controlled to be a desirable profile. This is because it is the two current constriction layers and the semiconductor layer disposed there between that controls the current distribution flowing into the quantum well layer to be a desirable profile. In Example 7, the current constriction structure provided by the insulation opening formed in the oxidation constriction layer 306 and the insulation film 361 includes two current constriction layers, and utilizes the spread of the current in the semiconductor layer disposed there between. Therefore the effect of the invention is implemented regardless whether the ITO layer is in direct contact with the layer that functions as the DBR.

ITO is normally an n-type semiconductor, and the ITO layer 362 of Example 7 is also an n-type semiconductor. This means that the junction interface with the thick film contact layer 3400, which is p-type semiconductor layer, is the p-n junction where a depletion layer is generated. Therefore the width of the film thickness on the p-type semiconductor layer side where holes exist becomes narrower by the width of the depletion layer. Further, the holes decrease in an area near the junction interface, due to the level of defects that exist in the junction interface with the ITO layer 362.

Therefore in the case of the contact using the ITO layer, a contact layer having a thicker film thickness than a common contact using a p-type contact electrode may be required, depending on the condition of the carrier density of the ITO layer, or the like. In such a case, the configuration of Example 7, where the film thickness of the contact layer can be increased to be an integral multiple of the optical film thickness λc/2 without changing the reflectance of the upper portion of the VCSEL, has advantages.

As described in Example 7, in the present invention, the spread of the carriers is controlled using the two current constriction structures and the semiconductor layer disposed there between. Therefore the total film thickness of the semiconductor layer between the two current constriction structures is also an important parameters. For example, if the film thickness of an appropriate number of pairs is set from the perspective of ensuring the reflectance of the DBR, the film thickness required for an ideal spread of carriers may become inefficient. In this case, an appropriate film thickness can be designed by disposing a semiconductor layer, of which optical film thickness is an integral multiple of λc/2, between the ITO layer and the DBR. Thereby both ensuring the reflectance of the DBR and controlling the spread of carriers can be implemented.

In the configuration of Example 7, the thick film contact layer 3400 is disposed in the VCSEL of Example 1, but the thick film contact layer 3400 may be disposed in any VCSEL of Examples 2 to 6. In any of these cases, both ensuring the reflectance of the DBR and controlling the spread of carriers can be implemented.

### Example 8

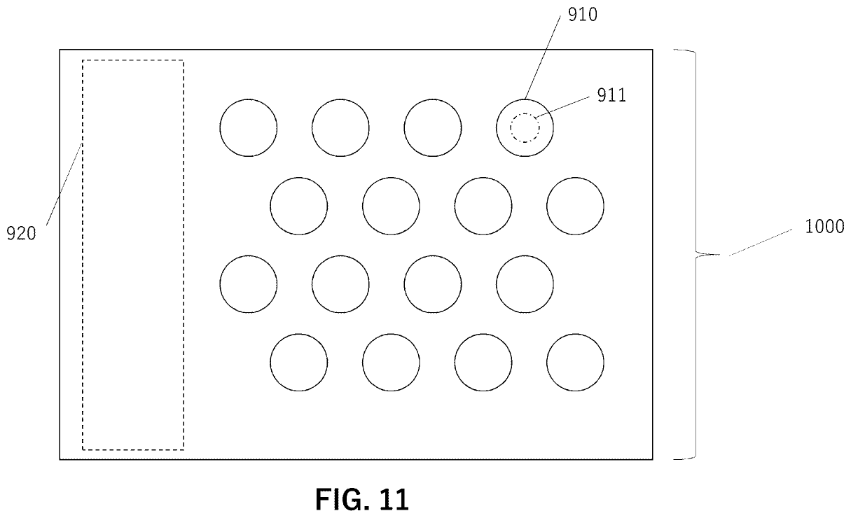

The VCSEL array 1000 according to Example 8 of the present invention will be described with reference to FIG. 11. In Examples 1 to 7, there is one VCSEL light-emitting portion, but the present invention is not limited to thereto, and a plurality of VCSEL light-emitting portions may be disposed.

As illustrated in FIG. 11, in the VCSEL array 1000 of Example 8, a plurality of VCSELs 300 described in Example 1 are disposed in an array. A circle 910 indicates an inner diameter of the upper ring electrode. A dashed line 911 indicates a light-emitting area, of which inner diameter is d1. A portion indicated by the dotted line is a pad portion 920 of the upper electrode.

As illustrated in FIG. 11, a plurality of light-emitting points are connected to a same electrode, and a plurality of light-emitting points emit light simultaneously. By using this configuration, the output from the light-emitting element can have even higher power.

In Example 8, 16 light-emitting points are arranged 4×4 in a triangular lattice, but the present invention is not limited thereto, and a number of light-emitting points and the arrangement of the light-emitting points may be changed to suit an application. In this example, the entire plurality of light-emitting points are simultaneously driven, but, depending on the application, the light-emitting points and the corresponding upper electrodes may be divided into a plurality of groups and driven, or individually driven so as to emit light at different timings.

Example 8 indicates a configuration in which the VCSEL of Example 1 is disposed in an array, but any VCSEL of Examples 2 to 7 may be disposed in an array. If the VCSEL according to Example 3 is disposed in an array, a larger diameter of the non-oxidized portion can be set than in the case of using the VCSEL according to Example 1 or 2, hence this array can implement higher power with a smaller area.

### Example 9

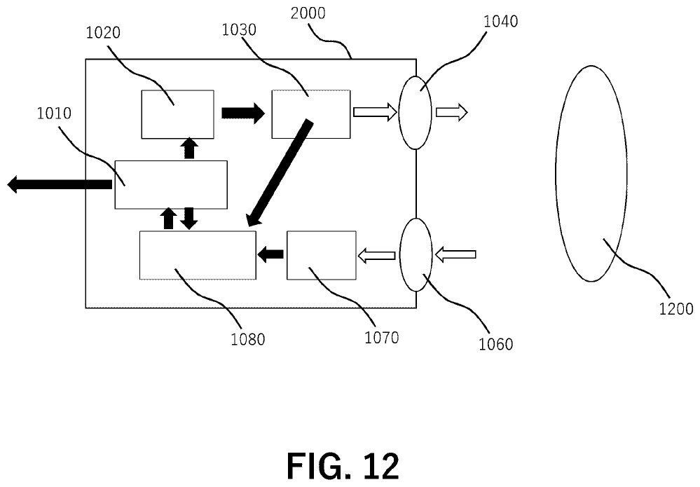

FIG. 12 indicates a ranging device 2000 according to Example 9. FIG. 12 is a laser light detection and ranging (LiDAR) device, in which a VCSEL of the above examples is used as a light source unit.

As indicated in FIG. 12, the ranging device 2000 is configured with a general control unit 1010, a VCSEL driver 1020, a VCSEL 1030, a light-emitting side optical system 1040, light-receiving side optical system 1060, a light-receiving image sensor 1070 and a distance data processing unit 1080.

In Example 9, the VCSEL 1030 is the VCSEL described in Example 1 is used, but the present invention is not limited thereto, and any VCSEL or VCSEL array described in Examples 1 to 8 may be used.

The VCSEL 1030 has a configuration in which a VCSEL described in the above examples is mounted in a package. Each of the light-emitting side optical system 1040 and the light-receiving side optical system 1060 may be one convex lens type member, or may be configured with a lens group where a plurality of lenses are combined. The light-receiving image sensor 1070 is an image sensor in which a single photon avalanche diode (SPAD) photosensor is disposed in a two-dimensional array.

An outline of the operation of the ranging device 2000 follows. First a driving signal is outputted from the general control unit 1010 to the VCSEL driver 1020. The VCSEL driver 1020, which received the driving signal, injects a predetermined value of current to the VCSEL 1030 to oscillate the VCSEL 1030.

The laser light generated in the VCSEL 1030 contacts a measurement target 1200 via the light-emitting side optical system 1040, and the light reflected by the measurement target 1200 enters the light-receiving image sensor 1070 via the light-receiving side optical system 1060. In this way, the reflected light of the light emitted from the VCSEL 1030 is detected by each pixel of the light-receiving image sensor 1070. It does not matter whether the distance data processing unit 1080 and the light-receiving image sensor 1070 are disposed in a same package, or are mounted on different packages, and electrically connected via a circuit board, as long as the distance data processing unit 1080 is electrically connected to the light-receiving image sensor 1070.

An electric signal pulse outputted from each pixel of the light-receiving image sensor 1070 is inputted to the distance data processing unit 1080. The distance data processing unit 1080 calculates the distance information in the light propagating direction based on the timing (detection timing) of the electric signal pulse outputted from each pixel of the light-receiving side optical system 1060, and generates and outputs three-dimensional information thereof.

In this way, the ranging device 2000 can acquire and output the three-dimensional information.

The ranging device 2000 can be applied to control to prevent collision with another vehicle, and control for driving automatically following another vehicle, or the like, in the automobile field. Further, the ranging device 2000 can be used for a moving body (moving device) of a ship, airplane, an industrial robot, or the like, and a moving body detection system. Furthermore, the ranging device 2000 can be applied to various equipment that three-dimensionally recognizes an object, including distance information.

The application of the three-dimensional information is not limited to the above. For example, the distance information may be used for image processing. When a virtual object is superimposed and displayed on an acquired image of a real space, the virtual object can be displayed naturally on the image of the real world by using the three-dimensional information of the real space. Further, by acquiring the three-dimensional information simultaneously when an image is acquired, blurs can be corrected based on the three-dimensional information after the image is captured.

### Other Embodiments

Whereas preferred embodiments have been described, the present invention is not limited to these embodiments, but may be modified and changed in various ways within the scope of the spirit thereof.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-000025, filed on Jan. 1, 2022 and Japanese Patent Application No. 2022-160460, filed on Oct. 4, 2022, which are hereby incorporated by reference herein in their entirety.

What is claimed is:

1. A semiconductor light-emitting element having a structure in which a substrate, a first reflector, a resonator cavity including an active layer, a second reflector and a transparent conductive film are stacked in this sequence, the semiconductor light-emitting element comprising:
a first current constriction portion configured with an oxidation constriction layer; and
a second current constriction portion configured with an insulation film, which is formed on an upper face of the second reflector and has an opening, and a contact portion between the transparent conductive film and a semiconductor layer with which the transparent conductive film is in contact,
wherein a width d2 of the second current constriction portion is smaller than a width d1 of the first current constriction portion.

2. The semiconductor light-emitting element according to claim 1, wherein the opening of the insulation film in the second current constriction portion is included in a non-oxidized portion on an inner side of the oxidation constriction layer in the first current constriction portion in planar view.

3. The semiconductor light-emitting element according to claim 1, wherein the width d1 of the first current constriction portion satisfies 30 μm≤d1≤70 μm.

4. The semiconductor light-emitting element according to claim 1,
wherein a tunnel junction layer is disposed on an uppermost portion of the second reflector, and
wherein the insulation film and the transparent conductive film are disposed on the tunnel junction layer, and the transparent conductive film is in contact with the second reflector via the tunnel junction layer.

5. The semiconductor light-emitting element according to claim 4, wherein the tunnel junction layer is disposed on the uppermost portion of the second reflector, so as to include at least a non-oxidized portion on an inner side of the oxidation constriction layer in the first current constriction portion in planar view.

6. The semiconductor light-emitting element according to claim 4, wherein the width d1 of the first current constriction portion satisfies 50 μm≤d1≤100 μm.

7. The semiconductor light-emitting element according to claim 1, wherein a transparent insulation film is disposed on the transparent conductive film.

8. The semiconductor light-emitting element according to claim 1, wherein a third reflector formed of a dielectric substance is further disposed on the second reflector.

9. A light-emitting device comprising, side-by-side, a plurality of the semiconductor light-emitting elements according to claim 1.

10. A ranging device comprising:
a light source including the semiconductor light-emitting element according to claim 1;
a sensor that detects reflected light of light generated by the light source; and
a processing unit that acquires distance information, based on a detection timing to detect the reflected light.
